(19) United States
(12) Patent Application Publication
(10) Pub. No.: US 2008/0277642 A1
(43) Pub. Date: Nov. 13, 2008

(54) Fabrication of Phase-Change Resistor Using a Backend Process

(75) Inventors: Michael A., A. In T Zandt, Veldhoven (NL); Martijn H., R. Lankhorst, Eindhoven (NL); Robertus A. M. Wolters, Eindhoven (NL); Hans Kwinten, Luyksgestel (NL)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 11/814,800

(22) PCT Filed: Jan. 19, 2006
(86) PCT No.: PCT/IB2006/050210

§ 371 Date: Jun. 2, 2008

(30) Foreign Application Priority Data
Jan. 25, 2005 (EP) 05100458.8

(51) Int. Cl. H01L 45/00

(52) U.S. Cl. 257/4; 438/102; 257/E45.002

(57) ABSTRACT

A phase change resistor device has a phase change material (PCM) for which the phase transition occurs inside the PCM and not at the interface with a contact electrode. For ease of manufacturing the PCM is an elongate line structure (210, 215) surrounded by the conductive electrode portions (200, 240) at its lateral sides, and is formed in a CMOS backend process. An alternative is to form the device coupled directly to other circuit parts without the electrodes. In each case, there is a line of PCM which has a constant diameter or cross section, formed with reduced dimensions by using a spacer as a hard mask. The first contact electrode and the second contact electrode are electrically connected by a “one dimensional” layer of the PCM. The contact resistance between the one-dimensional layer of PCM and the first contact electrode at the second contact electrode is lower than the resistance of a central or intervening portion of the line.

This invention relates to electrical devices having a resistor comprising a phase change material, and related integrated circuits and corresponding methods of manufacture as well as programmable devices such as logic or memory devices including the resistors as programmable elements.

Known programmable devices include programmable logic and programmable memory for example. They can be based on technology using fuses or antifuses to alter paths or connections between logic devices, or on technology based on changing a state of a material for example. In either case, devices can be categorized as re-programmable or one time programmable. They can also be categorized as non-volatile or volatile, depending on whether they lose their state when disconnected from a power supply. Known non-volatile memories include flash memories, FeRAMs, MRAMs, and programmable resistance devices such as phase-change memories.

A phase change memory is one example of memory based on the thermally programmable resistive properties of a material. Reference is made to S. Lai, “Current status of the phase change memory and its future”, Proc. IEDM 2003, p. 255. Electric current pulses of different magnitudes are passed from one electrode to the other and resistive heating is used to change the programmable material from the highly resistive amorphous state to the low resistive crystalline state and vice versa. Resistive materials such as a resistive electrode or a resistive layer can be used as a heat source located as close as possible to the programmable material.

Phase change materials may be programmed between a first structural state where the material is generally more amorphous (less ordered) and a second structural state where the material is generally more crystalline (more ordered). The term “amorphous” refers to a condition which is relatively structurally less ordered or more disordered than a single crystal and has a detectable characteristic, such as high electrical resistivity. The term “crystalline” refers to a condition which is relatively structurally more ordered than amorphous and has lower electrical resistivity than the amorphous state. The terms “crystalline” and “amorphous” are used to refer to a crystalline phase or a mainly crystalline phase, and to an amorphous phase or a mainly amorphous phase, respectively.

The phase-change material layer can comprise a chalcogenide material which is reversibly changeable in phase between an amorphous (noncrystalline) state of high resistance and a crystalline state of low resistance. The material is changed to the noncrystalline state or crystalline state by the passage of current to control the resistance value. For example when data is stored (SET), the phase-change material layer is changed from the amorphous state to the crystalline state and thereby given a low resistance value. When data is to be erased (RESET), the layer is changed from the crystalline state to the amorphous state to achieve a high resistance value. The difference in resistance value is read to use the layer as a memory. The high resistance state can represent for example, a logic ONE data bit, and the low resistance state can represent for example, a logic ZERO data bit.

Early phase change materials were based on changes in local structural order. The changes in structural order were typically accompanied by atomic migration of certain species within the material. Such atomic migration between the amorphous and crystalline states made programming energies relatively high, typically in the range of about a micro joule. This led to high current carrying requirements for address lines and for isolation between elements. Various arrangements have been tried to reduce the programming energy requirements. US patent application 2002/00011374 shows using multiple electrodes for each cell. Reduced energy by the appropriate selection of the composition of the memory material is described in U.S. Pat. No. 5,166,758. International patent application. It is known from U.S. Pat. No. 6,545,903 to use contact plugs above and below the phase change material as contact electrodes to program or erase the memory cell from the CMOS peripheral circuit.

US patent application 2004/0126925 explains that the minimum achievable dimension of a contact for a chalcogenide memory device is limited by lithography tools. The size of a contact, which is determined by the diameter of a pore, varies with the square of photolithography feature size error and also with the square of the variability in etch bias. Thus, step coverage also becomes an issue because aspect ratio in the pore increases as the pore diameter decreases. This leads to reduced yield, reduced reliability and reduced cycling endurance. This document shows forming a sidewall contact for the phase change material in the lower electrode portions in the CMOS controlled memory device. This means the size of the sidewall contact is the cross-sectional dimension of bottom electrode layer. The electrode layer is narrower than the phase change material at the contact.

US 2004/0043137 shows another example of a sidewall contact, by depositing phase change material on a multilayer structure. US 2004/0113192 shows a phase change memory using tapered contacts adjacent to the memory material. US 2004/0113232 shows a phase change memory having the phase change material contacted by at bottom and sides by one electrode, and at the top by another electrode. The top electrode makes contact through an opening having a sub lithographic diameter to reduce current consumption. Spacers can be used to reduce the contact area.

WO 2004/057618 explains that for a transition to a phase with a relatively poor conductivity such as an amorphous phase, heating by a sufficiently strong current melts the phase change material. The phase change material then cools down and assumes a more amorphous order. When inducing a transition to a phase with a relatively high electrical conductivity, the heating is initially counteracted by the poor conductivity, which limits the current conducted through the phase change material. It is believed that by applying a sufficiently high voltage, i.e. a voltage higher than the so-called threshold voltage, across the resistor it is possible to locally induce an electrical breakdown in the phase change material, which leads to a high local current density. The corresponding heating is then sufficient to increase the temperature of the phase change material to above its crystallization temperature, thereby enabling the phase transition from the amorphous phase to the crystalline phase. However, when repeatedly switched between the first phase and the second phase, i.e. the lifetime, also called the life span or the endurance, of the electrical device is limited. This is because the phase change material melts first at the point of smallest cross section, which is located in an aperture in contact with the resistive heater element. At this interface, i.e. at this contact area, repetitive phase changes and the corresponding high current densities cause a deterioration of the material, particularly when the phase change material comprises relatively reactive atoms such as Te. WO 2004/057618 proposes a different solution, increasing the contact area rather than reducing it. The phase change material constitutes a conductive path between a first contact area and a second contact area, a cross-section of the conductive path being smaller than both the first contact and second contact areas, so that the minimum cross-section of the conductive path is well inside the phase change material. This means the highest current density is kept away from the contact area, to increase lifetime.

An object of the invention is to provide improved electrical devices having a resistor comprising a phase change material, related integrated circuits and programmable devices such as logic or memory devices and corresponding methods of manufacture.

According to a first aspect, the invention provides an electrical device having a resistor comprising a phase change material being changeable between a first phase and a second phase, the resistor having a first electrical resistance when the phase change material is in the first phase, and a second electrical resistance, different from the first electrical resistance, when the phase change material is in the second phase, the phase change material constituting a conductive path between a first contact area and a second contact area, to provide a higher current density away from the contact areas than a current density at the first contact area and a current density at the second contact area, the resistor having an elongate shape with a substantially constant cross section along its length.

This helps enable the manufacturing to be simplified compared to that required for more complex shapes which may need separate processing for different parts of the shape.

A second aspect provides a method of manufacturing an electrical device having a resistor comprising a phase change material being changeable between a first phase and a second phase, the resistor having a first electrical resistance when the phase change material is in the first phase, and a second electrical resistance, different from the first electrical resistance, when the phase change material is in the second phase, the method having the steps of forming a structure of the phase change material to constitute a conductive path between a first contact area and a second contact area, such that the cross-section of the conductive path is smaller than the first contact area and the second contact area, and forming all parts of the structure in the same manner.

This can save manufacturing steps compared to the case where separate process steps are used for laying the contact areas of the phase change material and for producing the very narrow strip of the phase change material between the contact areas.

Other aspects can include methods of manufacturing corresponding to the first and second device aspects.

As additional features for dependent claims, the phase change material resistor is arranged on top of selecting device such as a transistor device, e.g. an MOS device, a BICMOS device, a Bipolar device, etc. This can be used for selecting the resistor for example. Another such additional feature is a via for coupling the first or second contact area to the selecting device, e.g. MOS device or other as indicated above.

Another such additional feature is a contact electrode arranged at the first or second contact area. This can serve to reduce contact resistance, though the manufacturing can be simplified if the contact electrodes are omitted.

Vias may also be used to connect the first and/or second contact area to selection lines. Such a via may be processed so that it lies adjacent to or next to the PCM-line but without touching the line. An advantage of this arrangement is that the PCM material does not have to etched, or the etch-process does not have to stopped at the PCM when forming the vias. The PCM can be used as a contact electrode. Preferably the PCM is used as a contact material on top of another electrode material. Alternatively a contact electrode can be placed below the PCM line, or the contact electrode can be placed above and on the sides of PCM-line.

Another such additional feature is the resistor being formed on a flattened top surface of the MOS device. This can enable the resistor to be formed more easily and reliably than if it is formed over a step for example.

Another such additional feature is the first and second contact areas each extending over two or more faces of the resistor. This can serve to increase the ratio of contact area to size of the resistor, and so improve density of integration.

Another such additional feature is the first and second contact areas being arranged to surround respective ends of the resistor. Again this can serve to increase the ratio of contact area to size of the resistor, and so improve density of integration.

Another such additional feature is the resistor having an elongate shape with a substantially constant cross section along its length.

An additional such feature for the methods, is the step of forming electrodes for both contact areas.

Another such additional step is flattening a top surface before forming the resistor.

Another such additional step is forming the resistor by forming a layer of resistor material, then a sacrificial layer to have an edge at the location of the resistor, forming a spacer hard mask at the edge, removing the sacrificial layer and removing the resistor material other than the part masked by the spacer hard mask. This enables the shape of the resistor to be made thinner than is otherwise practical.

Another such step is forming a top layer of the electrodes over the resistor to surround the ends of the resistor. This increases the surface area of the contact areas.

Another aspect provides an integrated circuit having the device set out above. The present invention also provides programmable devices include programmable logic and programmable memory for example. Change of the resistance of the resistor can be used to alter paths or connections between logic devices. Devices provided by the present invention include re-programmable or one time programmable devices as well as non-volatile devices, e.g. programmable resistance devices such as phase-change memories.

An example of such a devices provided by the present invention is memory device which comprises cells, each cell having a selection means and being connectable to addressing lines.

Any of the additional features can be combined together and combined with any of the aspects. Other advantages will be apparent to those skilled in the art, especially over other prior art. Numerous variations and modifications can be made without departing from the claims of the present invention. Therefore, it should be clearly understood that the form of the present invention is illustrative only and is not intended to limit the scope of the present invention.

How the present invention may be put into effect will now be described by way of example with reference to the appended drawings which all show embodiments of the present invention:

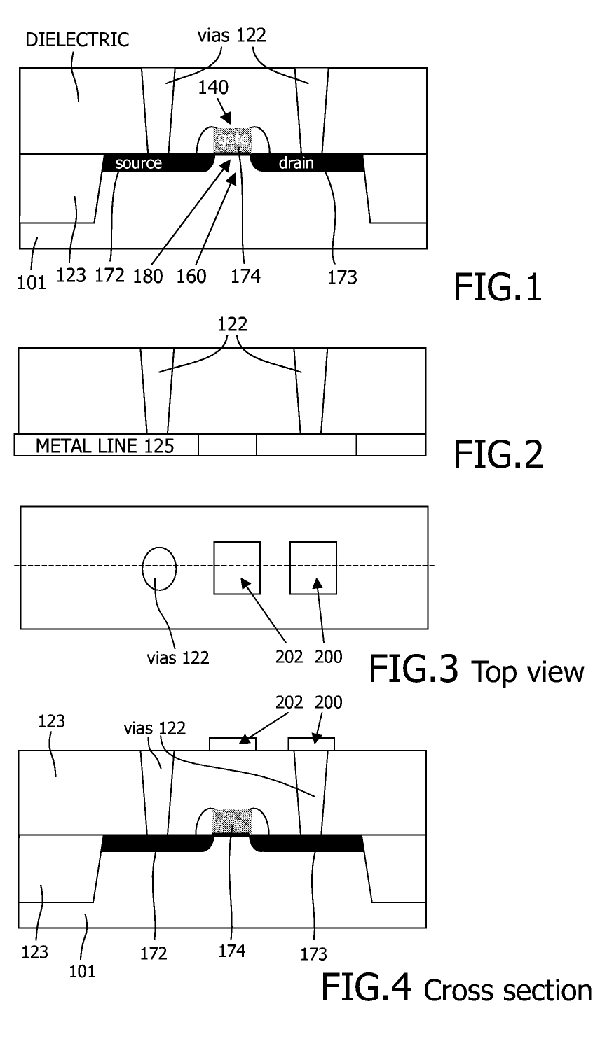

FIGS. 1 and 2 show a cross-section of vias connected to a MOS transistor or metal line.

FIGS. 3 and 4 show a top view and cross-section, respectively, of the electrodes definition.

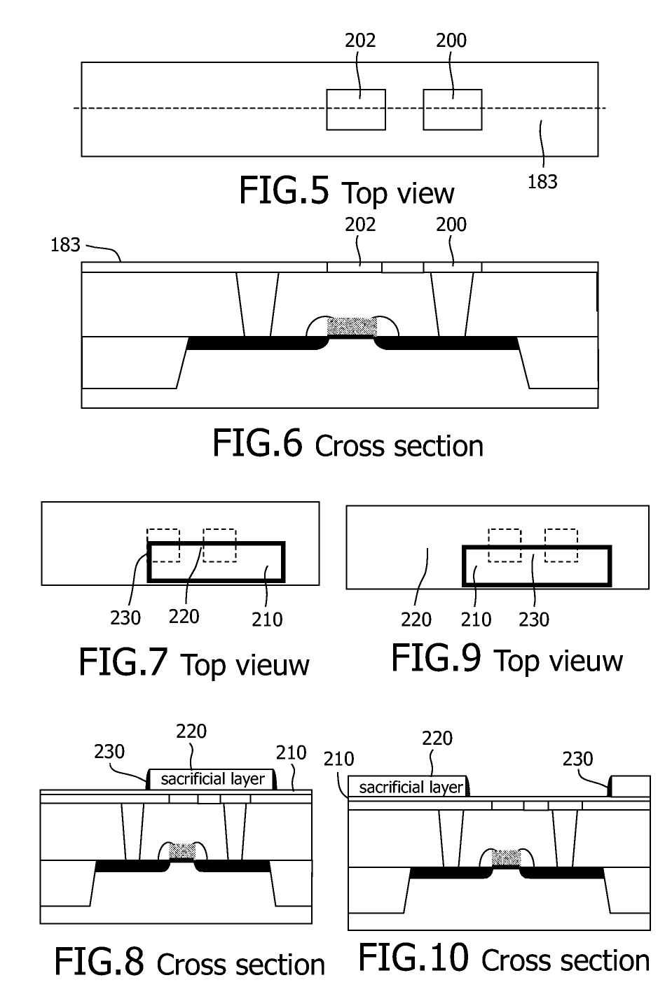

FIGS. 5 and 6 show a top view and cross-section, respectively, of the electrodes definition using a CMP-step.

FIGS. 7 to 10 show a top view and cross-section, respectively, of the spacer hard mask definition.

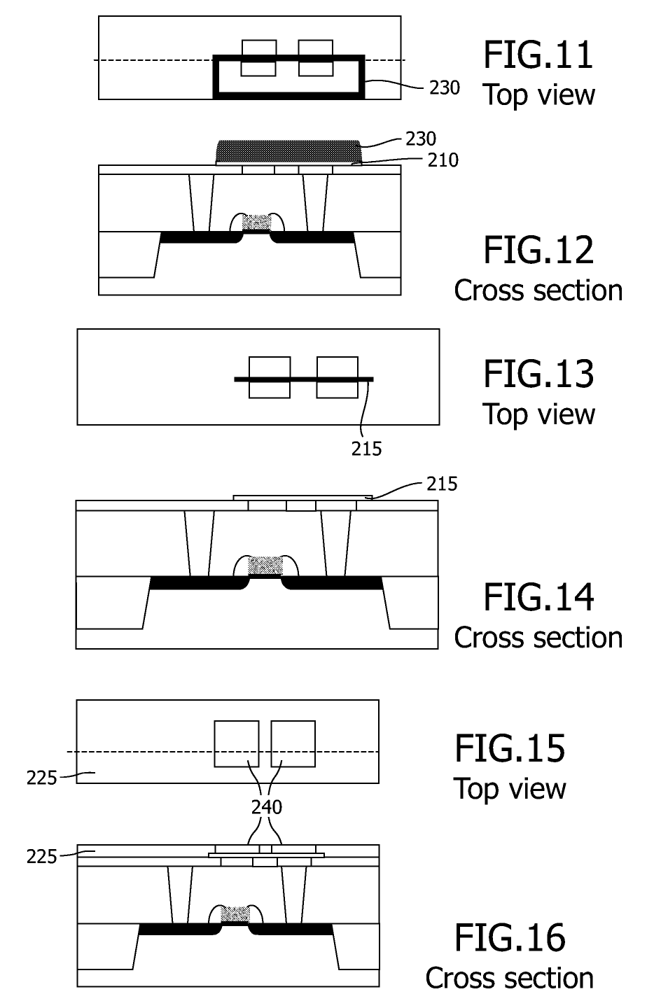

FIGS. 11 and 12 show a top view and cross-section, respectively, of the PCM-line underneath the spacer hard mask.

FIGS. 13 and 14 show a top view and cross-section, respectively, of the PCM-line on top of two electrodes.

FIGS. 15 and 16 show a top view and cross-section, respectively, of the PCM-line between two electrodes.

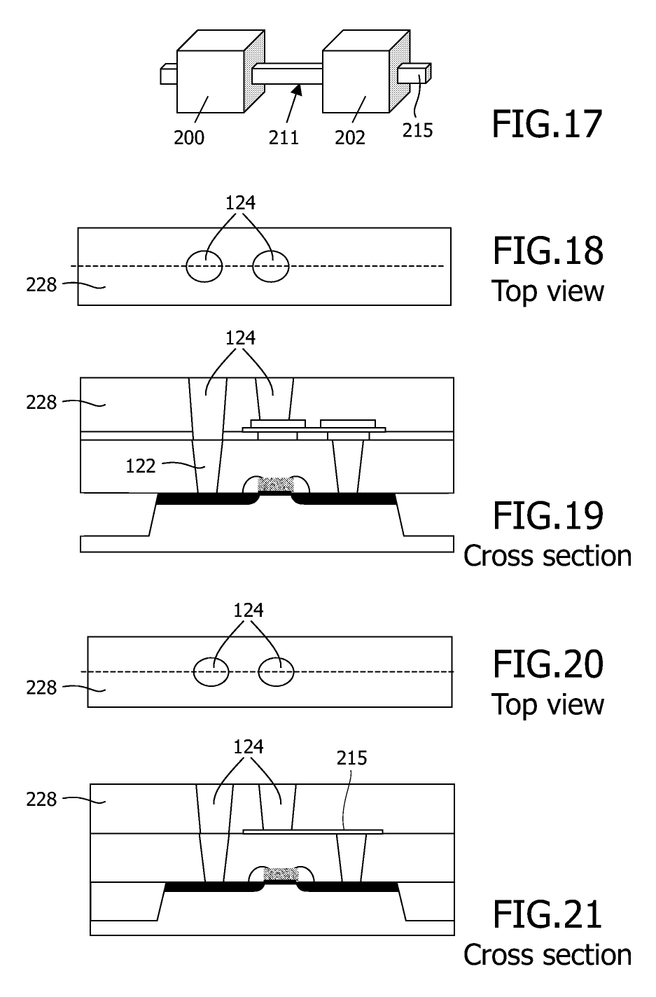

FIG. 17 show three-dimensional view of the PCM-line between two electrodes.

FIGS. 18 and 19 show a top view and cross-section, respectively, of the PCM connected to copper vias.

FIGS. 20 and 21 show a top view and cross-section, respectively, of an alternative embodiment with the PCM connected to copper vias without electrodes.

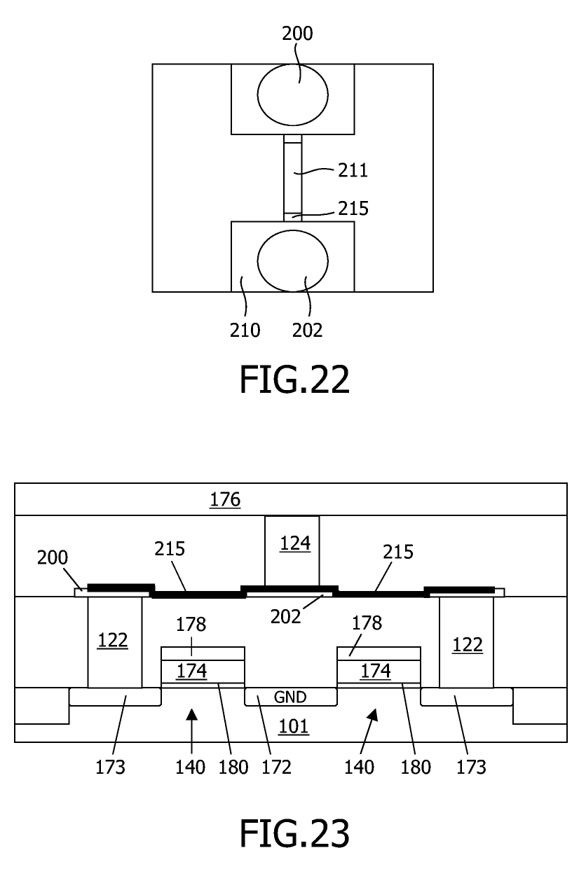

FIG. 22 shows a schematic arrangement of a PCM line formed between two contact areas.

FIG. 23 is a schematic cross section through a memory cell.

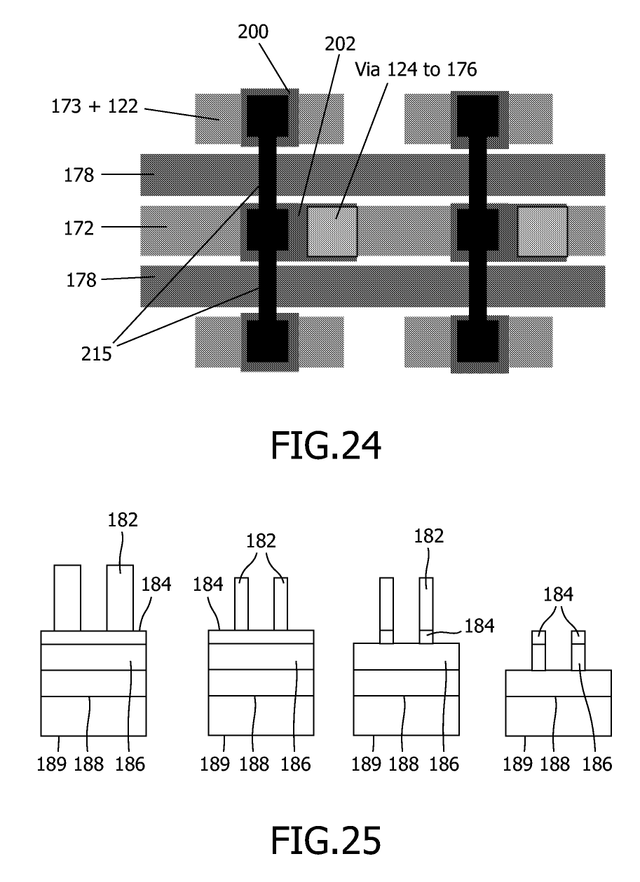

FIG. 24 is a top view of the memory cell of FIG. 23.

FIGS. 25 to 27 are alternative methods of manufacturing a narrow line useful for making the PCM-line structure of the present invention.

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes. Where the term “comprising” is used in the present description and claims, it does not exclude other elements or steps. Where an indefinite or definite article is used when referring to a singular noun e.g. “a” or “an”, “the”, this includes a plural of that noun unless something else is specifically stated.

In any of the embodiments of the present invention the resistive elements are preferably elongate resistive elements, e.g. in strip form. These strips are shown schematically in the figures. Such elongate elements have a longitudinal direction parallel to the longest dimension.

Some embodiments are based on arrangements as shown in WO 2004/057618 in which the Joule heating at the first contact area and/or the Joule heading at the second contact area are each smaller than the Joule heating inside the volume of the phase change material where the current density is high. This further reduces the interactions between the phase change material and the other materials at the first contact area and/or the second contact area, leading to an improved endurance. An additional advantage is that the electric power is dissipated, i.e. converted to heat, mainly at the location where the phase change occurs. By reducing the dissipation at positions where the phase change does not occur, the total electric power required for inducing a phase transition is reduced. It is based on making a thin line of phase-change material (PCM) that is connected to larger areas of PCM. Electrodes make contact to these larger areas. For low power switching, the effective cross-section of the line should be as small as possible.

The advantage of this kind of line-structure is that the highest current density and highest resistance is in the PCM-line. The electrode-PCM interfaces have relatively low current density and low resistance (low temperature, low power loss). An additional advantage of this structure is the relatively good thermal insulation of the switching part (melting part) of the PCM-line.

Various embodiments of the present invention, with various variations, illustrated in FIGS. 1 and 3-24 show a phase change device having a phase change material line structure optionally surrounded by the conductive electrode portions at at least one of its sides, e.g. at its lateral sides and/or top and bottom, in a semiconductor manufacturing process such as a CMOS backend process. An embodiment shown in FIGS. 20 and 21 shows a device having a phase change material line structure without electrodes in a semiconductor process e.g. the CMOS backend process. The present invention and its embodiments are not limited to MOS processing and MOS transistors. For example a transistor manufactured in accordance with the present invention, e.g. as a selection device, may be any suitable type of transistor, e.g. a bipolar transistor.

In each case, there is a layer of phase change material (PCM) which has a cross section. The PCM material is preferably in an elongate form, e.g. strip or stripe. The phase change material can be in the form of a line and the cross-section of the line is more or less constant but this is not so critical, since thermal diffusion can compensate for some variations along the line. Variations in cross-section of up to 30% would be acceptable. The smallest cross-section should preferably be more to the center of the line, rather than close or above the contact areas. It is also preferable that all the lines in a memory have more or less the same electrical resistance, and require the same programming power. It is preferred if the effective cross-section were to be the same for all lines. The embodiments also show a method of manufacturing an electrical device with a layer of phase change material wherein the phase transition occurs inside the phase change material and not at the interface with a contact electrode. The phase change takes place away from the electrode material in the PCM itself. Also the present invention can provide improved manufacturability by forming the phase change material with the reduced dimensions by using a spacer as a hard mask.

In these embodiments a first contact electrode 200 and a second contact electrode 202 are electrically connected by a “one dimensional” stripe 215 of PCM. The dimensions of the PCM stripe 215 formed from a PCM layer can be: width 5-100 nm (preferably 20-50 nm), and height or thickness PCM layer, 3-30 nm (preferably 5-15 nm). The contact resistance between the one-dimensional layer of phase change material 210 and the first contact electrode 200 and the second contact electrode 202 is lower than the resistance of a central or intervening portion of the line 215. The first contact electrode 200 and/or the second contact electrode 202 may comprise a layer of phase change material 210, preferably on top. This has the advantage that the contact resistance between PCM-stripe 210 and contact electrode 200, 202 can be made low.

The second contact electrode 202 may be deposited inside a contact hole analogously to a barrier layer. In that case the first electrode 200 preferably also has such a barrier layer because of symmetry. But, this first electrode 200 doesn't need a contact hole on top like the second electrode 202.

Methods of fabrication of phase-change devices such as programmable devices including programmable logic and programmable memory for example. For example logic devices are included within the scope of the present invention wherein change of the resistance of the phase change material is used to alter paths or connections between logic devices. Such devices can be made re-programmable or one time programmable. Further devices in accordance with the present invention may be described as non-volatile. Hence the present invention provides memories such as phase-change memories.

As an embodiment of the present invention memory cells manufactured by a semiconductor process such as a CMOS backend process will now be described with reference to FIGS. 1 to 27 as embodiments of the present invention. The electric device shown in FIGS. 1 and 3-24 at various stages of the manufacturing, has a selection device such a transistor 140 on a substrate 101. The transistor 140 may be an MOS device, or any other suitable selection device such as a bipolar, or BICMOS transistor. In accordance with any of the embodiments of the present invention this substrate 101 may comprise, e.g. a single crystal p-doped silicon semiconductor wafer. The term “substrate” may include any underlying material or materials that may be used, or upon which a device, a circuit or an epitaxial layer may be formed. In other alternative embodiments, this “substrate” may include a semiconductor substrate such as e.g. a doped silicon, a gallium arsenide (GaAs), a gallium arsenide phosphide (GaAsP), an indium phosphide (InP), a germanium (Ge), or a silicon germanium (SiGe) substrate. The “substrate” may include for example, an insulating layer such as a Sio₂ or an Si₃N₄ layer in addition to a semiconductor substrate portion. Thus, the term substrate also includes glass, plastic, ceramic, silicon-on-glass, silicon-on sapphire substrates. The term “substrate” is thus used to define generally the elements for layers that underlie a layer or portions of interest. The device may form part of an array of memory cells, each memory cell comprising a respective memory element and a respective selection device. Each memory cell may be individually addressable. There can be a grid of selection lines such that each memory cell is individually accessible via the respective selection lines connected to the respective selection device as shown in more detail in WO 2004/057618.

In the embodiment shown in FIGS. 1 and 3-24 the selection device comprises a metal oxide semiconductor field effect transistor (MOSFET), for example an NMOS transistor. The present invention is not limited to an NMOS selection device. The MOSFET has first main electrode regions having a first conductivity, e.g. n-doped source regions 172, second main electrode regions having the first conductivity, e.g. n-doped drain regions 173, and control electrode regions, e.g. gate regions 174. Where the selection device is a bipolar transistor the source, drain and gate are emitter, collector and base, respectively.

Returning to the MOS transistor 140 as an example: the source regions 172 and the drain regions 173 may comprise more than one portion of n-doped material, such as a lightly doped n-portion and a more heavily doped n+portion. The n-doped source region 172 and the drain region 173 are separated by a channel region 160. The gate regions 174, formed above the channel region 160, control the flow of current from the source region 172 to the drain region 173 through the channel region 160. The gate region 174 preferably comprises a conductive layer such as a layer of polycrystalline silicon or a metal. The gate region 174 is separated from the channel region 160 by a gate dielectric layer 180.

The grid of selection lines for a typical memory array comprises N first selection lines and M second selection lines, and an output line. The resistor of each memory element electrically connects one of the first or second main electrode regions, either the source region 172 or the drain region 173 of the corresponding selection device, e.g. MOSFET to the output line. The other of the first and second main electrode regions of the corresponding selection device, e.g. MOSFET selected from the drain region 173 and the source region 172 and being free from contact with the first main electrode region, is electrically connected to one of the N first selection lines. The control electrode, e.g. gate region 174 is electrically connected to one of the M second selection lines. The selection lines are typically connected to line selection devices and row selection devices, respectively, as well as read/write circuitry (not shown).

The gate region 174 and the drain region 173 can be provided with contact layers, e.g. of metal silicide such as tungsten silicide or Co- or Ni-silicide, as contacts, and vias in the form of metal plugs 122 such as tungsten plugs, e.g. tungsten with a Ti/TiN barrier, for electrically connecting the gate region 174 and the drain region 173 to the selection lines. The selection lines are formed from a conductive material such as a metal, e.g. aluminum or copper. The source region 172 is provided with a contact layer, e.g. of metal silicide (selected as above) and a metal, e.g. tungsten, plug as well.

In a process of manufacturing the device, typically first the array of selection devices, e.g. MOS selection devices or similar are formed, then the resistors and then the grid of selection lines, e.g. using standard IC technology. Other sequences are possible. The selection device 140, e.g. transistor, the selection lines and the vias are mutually insulated from each other by and embedded in a dielectric material 123, e.g. silicon dioxide. Preferably, the surface comprising the exposed via is polished by any suitable technique, e.g. chemical mechanical polishing (CMP) for obtaining a relatively smooth and relatively plane surface, as shown in FIG. 1. FIG. 2 shows an alternative in which the resistor is to be formed above a metal line 125 which can be a select line, or other interconnect. In this case, only one via is contacted to the metal-line. Hence, the vias are connected to separate metal lines.

The process steps for making contact electrodes 200, 202 and a resistor 211 formed in a PCM line 215 of PCM 210 will now be described. On top of the dielectric 123 (e.g. SiO₂), a layer of conductive electrode material (e.g. TiN, TaN, TaSiN, TiW) is deposited, patterned and etched. Assuming that the phase-change memory cells need a connection to the second main electrode of the selection device, e.g. the drain 173 of the selection devices, e.g. MOS transistors, the situation is then as sketched in FIG. 3 (top view) and FIG. 4 (cross section). This shows two electrodes 200, 202 one (200) coupled to the drain 173 and the other (202) unconnected. It is also possible as an option to put a contact on the source-plug 122. This may make the process easier because then all plugs 122 are created in the same way.

Another option is to deposit a dielectric layer 183 (e.g. SiO₂) first, etch contact holes, fill these holes with electrode-material to form contact electrodes 200, 202 and do a polishing step such as a CMP-step to flatten the surface while leaving the top of the electrodes 200, 202 exposed. This option is shown schematically in FIGS. 5 and 6. Otherwise, the features shown in FIG. 6 match those of FIG. 4. An advantage of these extra process steps is that they can produce a flatter surface before depositing the PCM. Defining the PCM-line becomes then much easier.

After the electrode definition, PCM is deposited to form the resistor 211 (from layer 210 in FIGS. 7 to 10). The thickness of this layer will define the height of the final PCM-line 215. Optionally extra materials may be formed on top of this PCM: conductive material (e.g. a metallic layer such as TiN, TaN, TaSiN, TiW) as a parallel heater along the PCM-line (see WO 2004/057676); or a protective layer to protect the PCM (and/or parallel heater if present) against dry etching steps later in the process.

Then, a sacrificial layer 220 (e.g. SiO₂, Si₃N₄) is deposited and etched in such a way that the step in this sacrificial layer 220 is overlapping the electrodes 200, 202. After this, a thin layer, e.g. 20 nm of for example, Si₃N₄, SiO₂, SiC, TiW is deposited and anisotropically etched, e.g. by RIE-etching, into spacers 230 at the sidewalls of the sacrificial layer 220. These spacers 230 function as a hard mask to define the PCM-line 215. The spacers 230 can be made at the outside of a part of the patterned sacrificial layer 220 as shown in FIGS. 7 (top view) and 8 (cross section). An alternative shown in FIG. 9 and 10 is to make the spacers 230 at the inside of an etched part of the sacrificial layer 220. This depends on how the sacrificial layer 220 is patterned (see FIGS. 7 to 10).

After selectively etching the sacrificial layer 220, the PCM layer 210, and optional extra materials for parallel heater and/or protection as desired, is anisotropically etched, e.g. RIE-etched using the spacers 230 as a mask. The spacers 230 on top of the PCM layer 230 have now been used to pattern the PCM layer 210 into narrow lines 215 following the rectangular outline of the box or hole in the sacrificial layer 220 (FIGS. 11 and 12). The width of these lines 215 is defined by the spacer width.

Subsequently, the spacer hard mask 230 is etched away and with an additional mask the PCM-line 215 is etched in such a way that only the PCM-line 215 remains between the electrodes 200, 202. The PCM-line 215 may overlap the electrodes 200, 202. The result of this stage of the process is sketched in FIG. 13 (top view) and FIG. 14 (cross section).

The next step in the process is depositing a dielectric 225 (e.g. SiO₂, Si₃N₄, SiC) to insulate the PCM-line 215. Then, holes are etched into this insulation-layer 225 which open the insulation-layer on top of the electrodes 200, 202. To protect the PCM layer 210 and line 215 against this etch, the protective layer on top of the PCM (mentioned above), if present, may be useful if it is not a metal layer like TiW. If the protective layer is metal it is preferably removed before insulation of the PCM-line 215. Or after etching the holes in the dielectric, this protective layer can be removed. The distance between the contact-holes, defines the length of the effective part of the PCM-line 215.

It is an option to place some of the contact-holes somewhere else on the electrodes 200, 202, in such a way that holes on top of the PCM-line 215 are not opened. So, if the electrodes 200, 202 are more rectangular, for example, the contact holes can be placed on the electrodes 200, 202 just beside the PCM line 215. A disadvantage is that this will give a higher contact resistance between the electrode 200, 202 and the PCM-line 215 because the PCM-line 215 is not fully surrounded by electrode-material anymore (as in FIG. 17).

Then, a second layer 240 of electrode-material (or other conductive layer like TiN, TaN, TaSiN, TiW) is deposited and polished, e.g. with a CMP-step, towards the same level as the insulation-layer 225. This is shown in FIGS. 15 and 16. A three dimensional view of the resistor formed by the PCM line 215 and the electrodes 200, 202 is shown in FIG. 17.

An advantage of the process steps described above, is that a good connection is created between the PCM-line 215 and the electrodes 200, 202. At the position of the electrodes 200, 202, the PCM-line 215 is contacted by or optionally surrounded and contacted by conductive material of the electrodes 200, 202 that should give a relatively low contact-resistance. This may help to avoid melting of the PCM-line 215 at the electrode-PCM interface.

In the next step, a dielectric 228, e.g. SiO₂, is deposited and a standard copper damascene process can be carried out to provide vias 124 to couple the PCM line 215 and the resistor 211 made therefrom to higher layers (see FIG. 19) such as an interconnect (best shown in FIG. 23). Where a bipolar transistor is used for the selection device the selection lines would be typically connected to the emitter and base, the resistor to the collector. The other end of the resistor is connected to an output circuit (not shown).

Embodiments of the present invention include modified method steps and device structures than those described above. Firstly, one option is to provide no contact electrode material in contact with the PCM line 215. For instance one alternative is to leave out all process steps of creating electrodes around the PCM-lines 215 from the process and connect the PCM-line 215 directly to the vias (122 and/or 124). This is shown in FIGS. 20 and 21. An advantage is that less process steps are needed but the disadvantage is that the PCM-line is not connected symmetrically which can increase a risk of inducing uncontrollable temperature behavior since the contact-resistance between the via at the left side of the PCM-line will be different from the one at right side.

Another option is to provide only contact material below the PCM line 215 (as shown in FIG. 14). Still another option is to provide only contact material above the PCM line 215 or in still another to embodiment to provide contact material both below and on top (as shown schematically in FIG. 16) but not necessarily all around as in FIG. 17.

The phase change material 210 used for the resistor 211 in the above embodiments of the present invention can be any suitable material. For example, in one embodiment the phase change material has the composition Sb_{1-c}M_{c}, with c satisfying 0.05<c<0.61, and M being one or more elements selected from the group of Ge, In, Ag, Ga, Te, Zn and Sn. An electric device with a phase change material of this composition (but without the novel and inventive features of the present invention) is described in the European Patent Application number 03100583.8. Preferably, c satisfies 0.05<c<0.5. Even more preferably, c satisfies 0.10<c<0.5. A group of advantageous phase change materials has one or more elements M other than Ge and Ga in concentrations which in total are smaller than 25 atomic percent and/or comprises in total less than 30 atomic percent of Ge and/or Ga. Phase change materials comprising more than 20 atomic percent of Ge and Ga and one or more elements selected from In and Sn in concentrations which in total are between 5 and 20 atomic percent have a relatively high crystallization speed and at the same time a relatively high stability of the amorphous phase. Ge-Sb-Te materials may also be used.

In an embodiment the phase change material is a composition of formula SbₐTe_{b}X_{100-(a+b))} with a, b and 100−(a+b) denoting atomic percentages satisfying 1: <a/b<8 and 4<100−(a+b)<22, and X being one or more elements selected from Ge, In, Ag, Ga and Zn. Many other examples are possible. The phase change material may be deposited by sputtering as described in the article “Phase-change media for high-numerical-aperture and blue-wavelength recording” by H. J. Borg et al., Japanese Journal of Applied Physics, volume 40, pages 1592-1597,2001.

As described above, devices and a manufacturing method therefore are described for a programmable device implemented as a phase-change device with the phase change material implemented as an line as shown schematically in FIG. 22. In this arrangement the PCM is constricted to a narrow line between two contacts 200, 202. The phase change material in the form of a line 215 forms a resistor 211 between the two contact areas which however does not extend to the contact areas 200, 202. This resistor 211 is switchable between the two phases to thereby change the value of the resistance.

The programmable device may be a memory with cells, each memory cell including a resistor based on a line concept for a PCM layer. However the present invention is not limited to memories.

A cell of a memory in accordance with an embodiment of the present invention is shown schematically in FIGS. 23, 24. Two transistors 140 have a common first main electrode region, e.g. a source region 172 which is grounded, each have a second main electrode region 173, e.g. a drain region. Each drain region is connected through a via 122 to a contact material 200 which is in contact with a PCM line 215. The centre of the PCM line 215 is in contact with a further contact material 202. A via 124 contacts the centre of the PCM line to the bitline 176. Each transistor 140 also has a control electrode region, e.g. a gate region 174 connected to a word line 178. A top view is shown in FIG. 24 from which it can be seen that the upper via 124 which is contacted with the bit line 176 does not necessarily contact the PCM material directly but only the contact material 202 to the side of the PCM material. This is an option.

The use of a line of phase change material formed on a flat surface leads to a more uniform distribution of line dimensions and the associated cell parameters using only few additional mask-steps. These apparatus and methods are based on direct etching of a thin layer of a PC-material (e.g. 1-10 nm) that has been deposited on a flat horizontal surface. As such, the resulting cells can be clearly distinguished form cells made by anisotropical etching of a PCM layer deposited in a shallow trench. Minimal RESET-powers have been calculated as a function of square root of the cross-section of a PCM line for different dielectric environments. To obtain low RESET powers, it can be shown that a small cross-section of the PCM-line is required. Also good thermal insulation enabled by the low heat conductivity of the surrounding dielectric is beneficial for lowering the RESET-power. PCM films that can still show reversible amorphous-crystalline transitions are typically about 2-5 nm thick, e.g. in the range 1 to 10 nm. Optically, films as thin as 3-5 nm have been recorded with data. Structuring such films (1-10) nm by RIE-etching using very small resist lines (10-30 nm) obtained by the techniques of the present invention, results in cross-sections in the range: (2×10)−(10×30)) nm=(4.5-17)nm. According to calculations, the present invention provides the advantage of RESET-powers well below 100 mW.

The present invention includes a variety of methods for making the mask for the etching of the PCM. Examples are:

1. using a spacer as a hardmask as described above. The spacer can be a material such as a nitride; or

2. using resist/hardmask lines with narrow CD (5-40 nm) made with optical techniques and/or special resist/hardmask trimming techniques and/or resist overbake techniques.

Specific examples of such methods are:

1) The PCM-line 215 is made by direct structuring of a horizontal and thin PCM-layer (as described above).

2) Making resist lines with phase-shift mask (alternating).

3) Making resist/hardmask lines with binary imaging or phase-shift masking followed by resist/hardmask CD-reducing techniques. The CD-reducing techniques can be:

a) Trimming resist and/or hardmask (hardmask can be TEOS or amorphous carbon, for example)

b) Overbake of resist

c) Overbake of resist in combination with resist and or hardmask trimming.

Detailed steps of methods to trim the mask to provide a narrow line pattern for the PCM are shown in FIGS. 25 to 27.

In FIG. 25 the starting position is a normal lithographically patterned resist 182 applied to an artireflection coating 184 which overlays an advanced patterning film (APF) 186, e.g. an amorphous carbon layer. The layer 188 is the material to be patterned finally, e.g. a PCM, which overlays a substrate 189 comprising layers as disclosed above. In the first step the resist 182 is trimmed to reduce its width, e.g. by overbaking the resist. In the next step the antireflection coating 184 is etched away using the resist as a mask. Then the APF layer 186 is etched leaving a narrow hard mask for etching the PCM material. In this etch the resist material may be consumed.

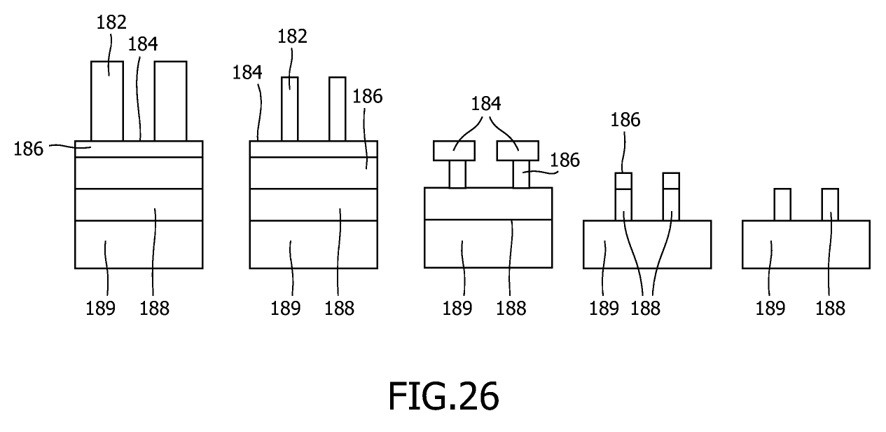

In FIG. 26 the starting position is a normal lithographically patterned resist 182 applied to an artireflection coating 184 which overlays an advanced patterning film (APF) 186, e.g. a carbon layer, as also shown in FIG. 25. The layer 188 is the material to be patterned finally, e.g. a PCM, which overlays a substrate 189 which includes layers as disclosed above. In the first step the resist 182 is trimmed to reduce its width, e.g. by overbaking the resist. In the next step the antireflection coating 184 and the APF is etched away using the resist as a mask to form a narrow hard mask. Then the narrow hard mask is used to etch the PCM material 188.

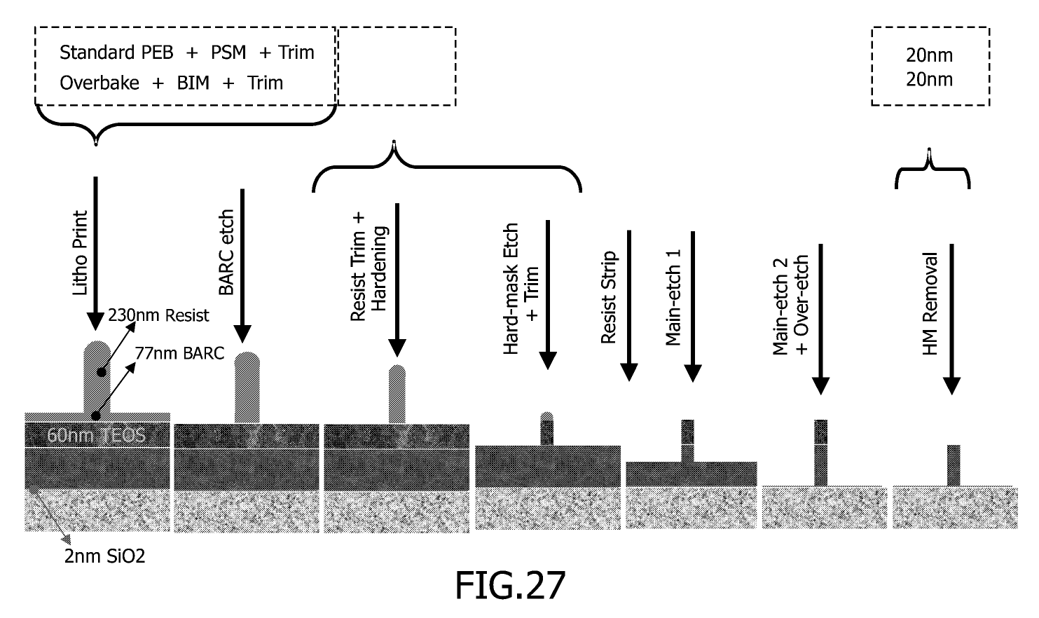

In FIG. 27 the starting position is a normal lithographically patterned resist 182 applied to an artireflection coating 184 which overlays a TEOS film 186. The layer 188 is the material to be patterned finally, e.g. a PCM, which overlays a substrate 189 comprising layers as disclosed above. In the first step the antireflection coating 184 is etched away using the resist as a mask. In the next step the resist 182 is trimmed to reduce its width, e.g. by overbaking the resist. Then the TEOS layer 186 is etched and optionally trimmed further to leave a narrow hard mask for etching the PCM material. The resist material may is then stripped and the PCM layer is etched in one or more steps. Finally the remains of the hard mask 186 is removed.

Other variations can be envisaged for both the devices and the methods of the present invention within the scope of the claims.

1. An electrical device having a resistor comprising a phase change material being changeable between a first phase and a second phase, the resistor having a first electrical resistance when the phase change material is in the first phase, and a second electrical resistance, different from the first electrical resistance, when the phase change material is in the second phase, the phase change material constituting a conductive path between a first contact area and a second contact area, to provide a higher current density away from the contact areas than a current density at the first contact area and a current density at the second contact area, the resistor having an elongate shape with a substantially constant cross section along its length.

2. The device according to claim 1, wherein the phase change material resistor is arranged on a selection device.

3. The device according to claim 3, wherein a via is provided for coupling the first or second contact area to the selection device.

4. The device according to claim 1 wherein a contact electrode is arranged at the first or second contact area.

5. The device according to claim 3, wherein the resistor is formed on a flattened top surface of the selection device.

6. The device according to claim 3, wherein the contact areas are buried in a dielectric layer.

7. The device according to claim 1, wherein the first and second contact areas each extend over two or more faces of the resistor.

8. The device according to claim 1 wherein the first and second contact areas are arranged to surround respective ends of the resistor.

9. A programmable device, comprising: —an array of cells, each cell comprising a respective programmable element and a respective selection device, wherein the resistor as claimed in claim 1 constitutes a programmable element; and a grid of selection lines, each cell being individually accessible via the respective selection lines connected to the respective selection device.

10. The programmable device in accordance with claim 9, wherein the device is a memory.

11. A programmable device as claimed in claim 10, wherein: —the selection device comprises transistor having a first main electrode region, a second main electrode region and a control electrode region, and the grid of selection lines comprises N first selection lines, M second selection lines, and an output line, the resistor of each programmable element electrically connecting a first region selected from the first electrode region and the second electrode region of the corresponding transistor to the output line, a second region of the corresponding the transistor selected from the first electrode region and the second electrode region and being free from connection to the first region, and being electrically connected to one of the N first selection lines, the control electrode region being electrically connected to one of the M second selection lines.

12. The programmable device of claim 11 wherein the transistor is a metal oxide semiconductor field effect transistor and the first electrode region is a source region, the second electrode region is a drain region and the control electrode region is a gate region.

13. The programmable device of claim 11 , wherein the transistor is a bipolar transistor and the and the first electrode region is an emitter region, the second electrode region is a collector region and the control electrode region is a base region.

14. A method of manufacturing an electrical device having a resistor comprising a phase change material being changeable between a first phase and a second phase, the resistor having a first electrical resistance when the phase change material is in the first phase, and a second electrical resistance, different from the first electrical resistance, when the phase change material is in the second phase, the method having the steps of forming a structure of the phase change material to constitute a conductive path by patterning a layer of the phase change material on a flat surface.

15. A method of manufacturing an electrical device having a resistor comprising a phase change material being changeable between a first phase and a second phase, the resistor having a first electrical resistance when the phase change material is in the first phase, and a second electrical resistance, different from the first electrical resistance, when the phase change material is in the second phase, the method having the steps of forming a structure of the phase change material to constitute a conductive path between a first contact area and a second contact area, such that the cross-section of the conductive path is smaller than the first contact area and the second contact area, and forming all parts of the structure in the same manner.

16. The method according to claim 15, further comprising forming electrodes for both contact areas.

17. The method according to claim 15, further comprising flattening a top surface before forming the resistor.

18 The method according to claim 14, further comprising forming the resistor by forming a layer of resistor material, then a sacrificial layer to have an edge at the location of the resistor, forming a spacer hard mask at the edge, removing the sacrificial layer and removing the resistor material other than the part masked by the spacer hard mask.

19. The method according to claim 14, further comprising forming a top layer of the electrodes over the resistor to surround the ends of the resistor.

20. An integrated circuit having a device according to claim 1.
